(19) United States
(12) Patent Application Publication
(10) Pub. No.: US 2009/0001448 A1
(43) Pub. Date: Jan. 1, 2009

(54) SEMICONDUCTOR MEMORY DEVICE AND METHOD OF MANUFACTURING THE SAME

(76) Inventors: Katsuyuki Sekine, Yokohama-Shi (JP); Masayuki Tanaka, Yokohama-Shi (JP); Katsuaki Natori, Yokohama-Shi (JP); Daisuke Nishida, Yokkaichi-Shi (JP); Ryota Fujitsuka, Yokohama-Shi (JP); Yoshio Ozawa, Yokohama-Shi (JP); Akihito Yamamoto, Kanagawa-Ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/118,328

(22) Filed: May 9, 2008

(30) Foreign Application Priority Data
May 11, 2007 (JP) 2007-126916

(51) Int. Cl. H01L 29/00; H01L 21/3205

(52) U.S. Cl. 257/321; 438/594; 257/E29.001; 257/E21.294

(57) ABSTRACT

A semiconductor memory device having a cell size of 60 nm or less includes a tunnel insulation film formed in a channel region of a silicon substrate containing a burying insulation film, a first conductive layer formed on the tunnel insulation film, an inter-electrode insulation film formed on the burying insulation film and the first conductive layer, a second conductive layer formed on the inter-electrode insulation film, a side wall insulation film formed on the side walls of the first conductive layer, the second conductive layer, and the inter-electrode insulation film, and an inter-layer insulation film formed on the side wall insulation film. The tunnel insulation film or the inter-electrode insulation film contains a high-dielectric insulation film. The side wall insulation film contains a predetermined concentration of carbon and nitrogen as well as chlorine having a concentration of 1×10¹⁹ atoms/cm³ or less.

### CROSS-REFERENCE TO RELATED APPLICATION

This application is based upon and claims the benefit of priority from the prior Japanese Patent Application No. 2007-126916, filed on May 11, 2007; the entire contents of which are incorporated herein by reference.

### BACKGROUND OF THE INVENTION

The present invention relates to a semiconductor memory device and a method of manufacturing the same, and, more particularly, to a semiconductor memory device having a cell size of 60 nm or less and a method of manufacturing the same.

As a non-volatile semiconductor memory device is miniaturized in size, it is requested to reduce the thickness of a tunnel insulation film to reduce a write voltage and to increase a write speed. Further, as a cell is miniaturized in size, since a problem arises in the deterioration of device characteristics due to an increase of interference effect between adjacent cells, it is indispensable to reduce the thickness of an inter-electrode insulation film. To satisfy these requests, it is examined to reduce the thickness of the tunnel insulation film and the inter-electrode insulation film by introducing a high-dielectric insulation film to the tunnel insulation film and the inter-electrode insulation film.

However, when the high-dielectric insulation film is introduced to the tunnel insulation film and the inter-electrode insulation film, there is a problem in that the charge holding characteristics of a miniaturized cell is greatly deteriorated. In particular, when a cell size is made to 60 nm or less, the charge holding characteristics are deteriorated outstandingly (Japanese Patent Application Laid-Open No. 6-13372).

### SUMMARY OF THE INVENTION

According to the first aspect of the present invention, there is provided that a semiconductor memory device having a cell size of 60 nm or less comprising:

a tunnel insulation film formed in a channel region of a silicon substrate containing a burying insulation film;

a first conductive layer formed on the tunnel insulation film;

an inter-electrode insulation film formed on the burying insulation film and the first conductive layer;

a second conductive layer formed on the inter-electrode insulation film;

a side wall insulation film formed on the side walls of the first conductive layer, the second conductive layer, and the inter-electrode insulation film; and

an inter-layer insulation film formed on the side wall insulation film,

wherein the tunnel insulation film or the inter-electrode insulation film contains a high-dielectric insulation film; and

the side wall insulation film contains a predetermined concentration of carbon and nitrogen as well as chlorine having a concentration of 1×10¹⁹ atoms/cm³ or less.

According to the second aspect of the present invention, there is provided that a method of manufacturing a semiconductor memory device having a cell size of 60 nm or less comprising:

forming a tunnel insulation film to a channel region of a silicon substrate;

forming a first conductive layer on the tunnel insulation film;

forming an inter-electrode insulation film on the first conductive layer;

forming a second conductive layer on the inter-electrode insulation film,

processing the second conductive layer, the inter-electrode insulation film, and the first conductive layer;

forming a side wall insulation film which contains carbon, nitrogen, and chlorine, to the side walls of the first conductive layer, the second conductive layer, and the inter-electrode insulation film;

forming an inter-layer insulation film on the side wall insulation film;

reducing the concentration of the chlorine contained in the side wall insulation film to 1×10¹⁹ atoms/cm³ or less by subjecting the entire surface of the side wall insulation film to a heat treatment in an atmosphere containing hydrogen and oxygen; and

forming a high-dielectric insulation film in the process for forming the tunnel insulation film or the inter-electrode insulation film.

### BRIEF DESCRIPTION OF THE DRAWINGS

FIG. 1A is a sectional view of a structure of cell transistor of a non-volatile semiconductor memory device of the first embodiment of the present invention.

FIG. 1B is a sectional view of FIG. 1A in the sectional direction of a broken line (b).

FIG. 2 is a graph showing the relation between a minimum processing size of a cell transistor and a charge holding time.

FIG. 3 is a sectional view showing a process of the method of manufacturing the non-volatile semiconductor memory device of the first embodiment of the present invention.

FIG. 4 is sectional view showing a process after the process showed in FIG. 3.

FIG. 5 is sectional view showing a process after the process showed in FIG. 4.

FIG. 6 is sectional view showing a process after the process showed in FIG. 5.

FIG. 7 is sectional view showing a process after the process showed in FIG. 6.

FIG. 8 is sectional view showing a process after the process showed in FIG. 7.

FIG. 9 is sectional view showing a process after the process showed in FIG. 8.

FIG. 10 is sectional view showing a process after the process showed in FIG. 9.

FIG. 11 is a sectional view of FIG. 10 in the sectional direction of a broken line (11).

FIG. 12 is a sectional view of a structure of a cell transistor of the non-volatile semiconductor memory device of the second embodiment of the present invention.

FIG. 13 is a sectional view of FIG. 12 in the sectional direction of a broken line (13).

FIG. 14 is a graph showing the relation between Cl concentration and a charge holding time of the cell transistor of the comparative example.

### DETAILED DESCRIPTION OF THE INVENTION

Embodiments of the present invention will be explained below referring to the drawings. Note that the embodiments described below are only examples of the present invention and do not restrict the scope of the present invention.

First, there will be explained a phenomenon in that charge holding characteristics are deteriorated when a high-dielectric insulation film is introduced to a tunnel insulation film and an inter-electrode insulation film in a semiconductor memory device having a cell size (a gate length in a lengthwise direction of a channel in a portion in contact with the tunnel insulation film) of 60 nm or less. Note that the high-dielectric insulation film of the embodiment of the present invention is an insulation film having a permittivity higher than that of a silicon nitride film.

When the high-dielectric insulation film is introduced to the tunnel insulation film and the inter-electrode insulation film, there is a phenomenon in that a shallow trap level which acts as a low electric field leak current path is created in the high-dielectric insulation film introduced to the tunnel insulation film and the inter-electrode insulation film as well as a deep trap level which accumulates a charge therein when data is written or deleted, and thereafter discharges the accumulated charge, is increased as the processing size of the cell is reduced, and thus the charge holding characteristics of the miniaturized cell are greatly deteriorated. In particular, the deterioration of the cell characteristics is prominently observed in a miniaturized cell having a cell size of 60 nm or less.

Further, the deterioration of the cell characteristics is mainly caused by a process damage which occurs when an insulation film for forming side walls of the tunnel insulation film and the inter-electrode insulation film is formed. More specifically, the deterioration is mainly caused by that the chlorine which is contained in a precursor of the side wall insulation film and remains in the side wall insulation film cuts off the coupling of the metal with the oxygen in the high-dielectric insulation film which is introduced to the tunnel insulation film and the inter-electrode insulation film, and generates a lot of oxygen deficiency in the high-dielectric insulation film when the side wall insulation film is formed.

### FIRST EMBODIMENT

Next, an first embodiment of the present invention will be explained. The first embodiment will be explained as to an example in which a high-dielectric insulation film is introduced to an inter-electrode insulation film as well as the concentration of chlorine contained in a precursor of a side wall insulation film is set to a low level.

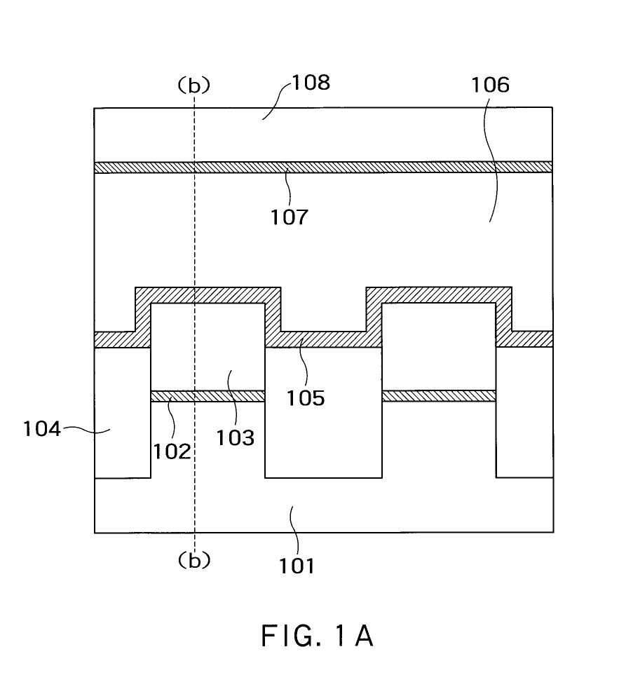

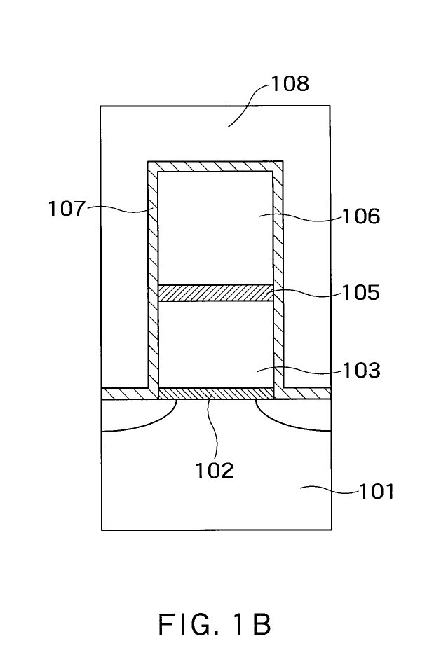

FIG. 1A is a sectional view of a structure of cell transistor of a non-volatile semiconductor memory device of the first embodiment of the present invention. FIG. 1B is a sectional view of FIG. 1A in the sectional direction of a broken line (b).

As shown in FIGS. 1A and 1B, the cell transistor of the first embodiment of the present invention includes a first insulation film (tunnel insulation film) 102 formed on a channel region between a source region and a drain region of a silicon substrate 101 with a buried insulation film for a isolation 104, a first conductive layer (floating gate electrode) 103 formed on the first insulation film 102, a second insulation film (inter-electrode insulation film) 105 having a high-dielectric insulation film formed on the first conductive layer 103 and the buried insulation film for the isolation 104, a second conductive layer (control gate electrode) 106 formed on the second insulation film 105, a side wall insulation film 107 formed on the second conductive layer 106, and an inter-layer insulation film 108 formed on the side wall insulation film 107.

Note that the average chlorine concentration in the side wall insulation film 107 is 1×10¹⁹ atoms/cm³ or less, and at least one of C and N is contained in the side wall insulation film 107 in the amount of at least 1×10¹⁹ atoms/cm³.

In the first embodiment of the present invention, the side wall insulation film 107 is formed by performing ALD (Atomic Layer Deposition) using for example, BTBAS (bis-(3 class-butylamino)silane)) and oxygen as a precursor at 400° C. to 600° C. In this case, since no chlorine is contained in the precursor that forms the side wall insulation film 107, no reaction due to chlorine is caused to the coupling of metal with oxygen. Further, no chlorine remains in the side wall insulation film 107, the high-dielectric insulation film in the second insulation film 105 is not deteriorated. Further, a suitable amount of C and N is introduced into the side wall insulation film 107 by the impurities contained in the precursor. Note that the substance which is used as the precursor when the side wall insulation film 107 is formed is not limited to BTBAS and oxygen and may be other substance containing silicon and carbon.

When the high-dielectric insulation film in the second insulation film 105 is formed to by CVD (Chemical Vapor Deposition) or ALD, the impurities contained in the precursor are contained in the high-dielectric insulation film in the amount of at least 1×10¹⁹ atoms/cm³ in a peak concentration. For example, when an organic metal material is used as the precursor at the time the high-dielectric insulation film is formed, carbon is contained in the high-dielectric insulation film, whereas when the precursor containing nitrogen is used, nitrogen is contained therein. Further, when the same type of impurities as those contained in the high-dielectric insulation film are previously contained in the side wall insulation film 107 in the amount of at least 1×10¹⁹ atoms/cm³ in a peak concentration, the mutual diffusion between the impurities in the side wall insulation film 107 and the impurities in the high-dielectric insulation film in the second insulation film 105 (in particular, diffusion of impurities from the high-dielectric insulation film in the second insulation film 105 to the side wall insulation film 107) is suppressed. As a result, the thermal stability of the interface between the silicon oxide film and the high-dielectric insulation film in the second insulation film 105 can be greatly improved.

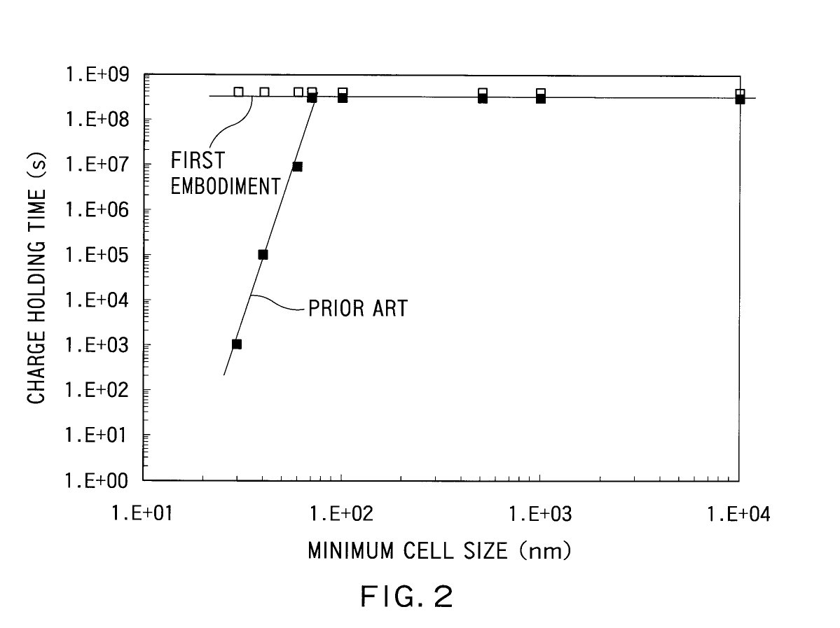

FIG. 2 is a graph showing the relation between a minimum processing size of a cell transistor and a charge holding time. In a prior art, when the size of a cell transistor is reduced to 60 nm or less, a high-dielectric insulation film is deteriorated, and the charge holding time is abruptly shortened. In contrast, in the first embodiment of the present invention, since the chlorine concentration in the side wall insulation film 107 is suppressed to a sufficiently low level, even if the size of the cell transistor is reduced to 60 nm or less, the high-dielectric insulation film is not deteriorated, and the charge holding time is not shortened. Further, the dependency of charge holding characteristics on the cell size which is found in the prior art is not found in the cell transistor of the first embodiment of the present invention.

According to the first embodiment of the invention, there can be provided a non-volatile semiconductor memory device excellent in the charge holding characteristics by suppress the chlorine concentration in the side wall insulation film 107 to a low level even if the high-dielectric insulation film is introduced to the second insulation film 105 when the size of the cell transistor is reduced to 60 nm or less.

Note that the second insulation film 105 may be a single high-dielectric insulation film layer, a stacked structure of a silicon oxide film/high-dielectric insulation film/silicon oxide film having the high-dielectric insulation film, a stacked structure of a silicon nitride film/high-dielectric insulation film/silicon nitride film, or a stacked structure of a silicon nitride film/silicon oxide film/high-dielectric insulation film/silicon oxide film/silicon nitride film. That is, as long as the second insulation film 105 contains the high-dielectric insulation film, the same effect can be obtained.

Although the first embodiment of the present invention explains the case that the high-dielectric insulation film is introduced to the second insulation film 105, the high-dielectric insulation film may be introduced to a part of the tunnel insulation film 102. In this case, since the buried insulation film for the isolation 104 and the side wall insulation film 107 are in contact with the tunnel insulation film 102, the chlorine concentration in the side wall insulation film 107 is IE+19 atoms/cm³ or less. Thus, in this case, when at least one of C and N is contained in the amount of at least IE+19 atoms/cm³, the charge holding characteristics can be greatly improved likewise the case that the high-dielectric insulation film is introduced to the second insulation film 105.

It is preferable that the high-dielectric insulation films of the first and second insulation films 102 and 105 have a relative permittivity larger than that (the value of about 7) of the silicon nitride film (SiN film). This because if the SiN film is used as the high-dielectric insulation film of the first and second insulation films 102 and 105, sufficient leak characteristics cannot be obtained in a write/delete electric field necessary to the non-volatile semiconductor memory device.

There may be used a single layer film of any one of, for example, an aluminum oxide (Al₂O₃) film having a relative permittivity of about 8, a magnesium oxide (MgO) film having a relative permittivity of about 10, an yttrium oxide (Y₂O₃) film having a relative permittivity of about 16, a hafnium oxide (HfO₂) film having a relative permittivity of about 22, zirconium oxide (ZrO₂), and lanthanum oxide (La₂O₃).

Further, an insulation film containing a ternary compound such as a hafnium silicate (HfSiO) film and a hafnium aluminate (HfAlO) film may be used. That is, oxide or nitride containing at least one of silicon (Si), aluminum (Al), magnesium (Mg), yttrium (Y), hafnium (Hf), zirconium (Zr), and lanthanum (La) may be used.

### <Method of Manufacturing Non-volatile Semiconductor Memory Device of the First Embodiment of the Present Invention>

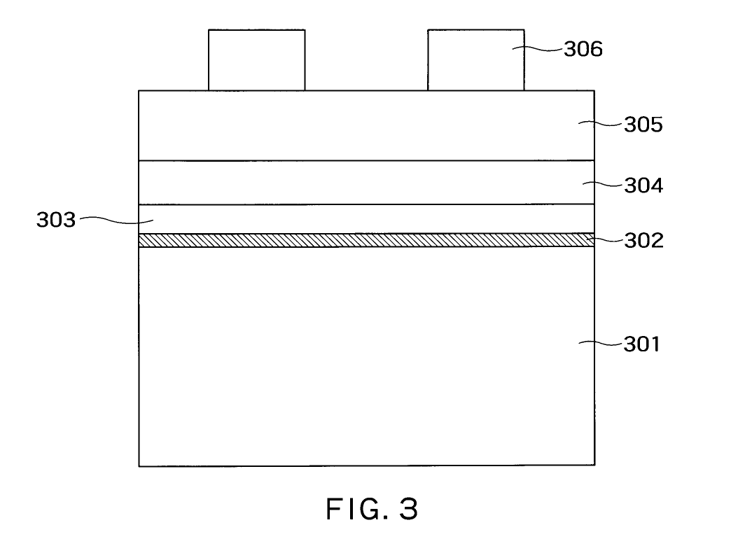

Next, a method of manufacturing the non-volatile semiconductor memory device of the first embodiment will be explained referring to FIGS. 3 to 11.

As shown in FIG. 3, a first insulation film 302 is formed on a silicon substrate (p-type silicon substrate or n-type silicon substrate having a p-type well formed thereon) 301 to a thickness of about 1 nm to 15 nm. Then, a first conductive layer 303 acting as a charge accumulation layer is formed on the first insulation film 302 to a thickness of 10 nm to 200 nm by CVD. Then, a silicon nitride film 304 is formed to about 50 nm to 200 by CVD. Then, a silicon oxide film 305 is formed to about 50 nm to 400 nm by CVD. Then, a photoresist 306 is coated on the silicon oxide film 305 and patterned by exposure drawing. After the above, the structure of FIG. 3 is obtained.

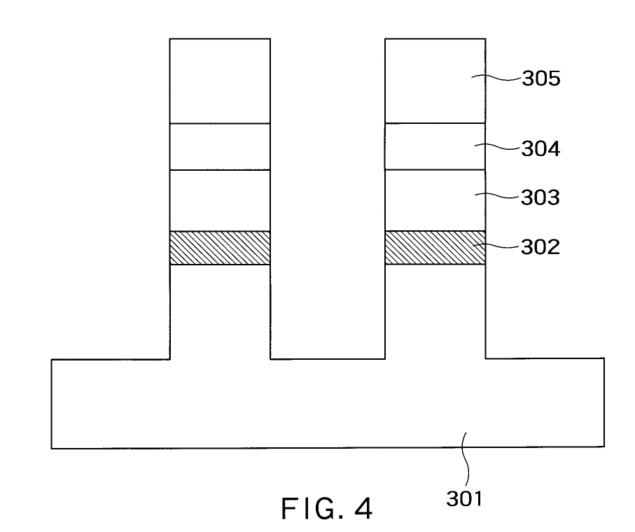

Next, as shown in FIG. 4, the silicon oxide film 305 is etched using the photoresist 306 shown in FIG. 3 as an etching-resistant mask. Then, the photoresist 306 is removed after the etching, and the silicon nitride film 304 is etched using the silicon oxide film 305 as a mask. Then, a groove for the isolation is formed by etching the first conductive layer 303, the first insulation film 302, and the silicon substrate 301. After the above, the structure of FIG. 4 is obtained.

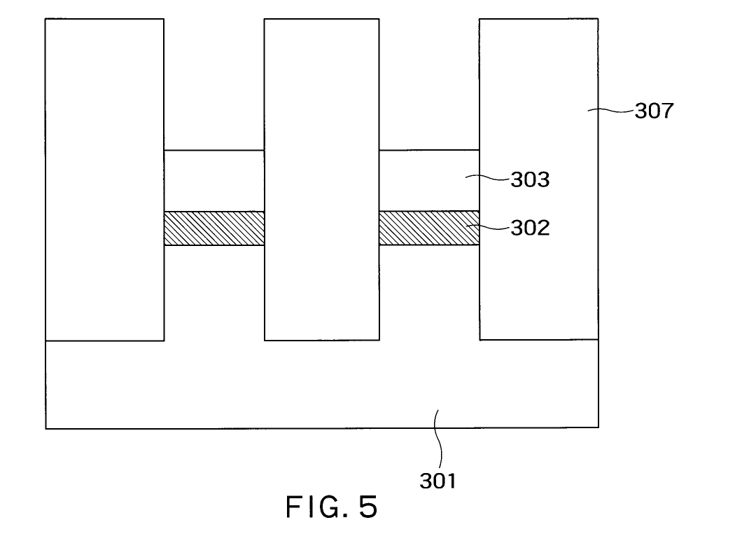

Next, as shown in FIG. 5, a buried insulation film 307 containing a silicon oxide film and the like is formed to a thickness of 200 nm to 1500 nm to fill the groove for the isolation. The buried insulation film 307 is subjected to a high temperature heat process in a nitrogen or oxygen atmosphere so that the density thereof is increased. Then, planarization is performed by CMP (Chemical-Mechanical Polishing) using the silicon nitride film 304 as a stopper. Then, the silicon nitride film 304 is removed by selective etching. After the above, the structure of FIG. 5 is obtained.

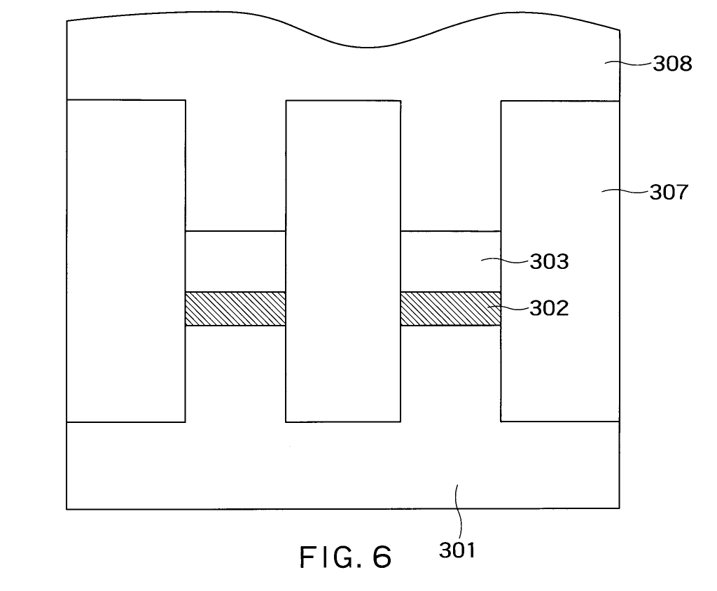

Next, as shown in FIG. 6, a second polysilicon conductive layer 308 which acts as a part of the first conductive layer 303 is deposited on a groove obtained after the silicon nitride film 304 is removed using a method excellent in a step covering property. After the above, the structure of FIG. 6 is obtained.

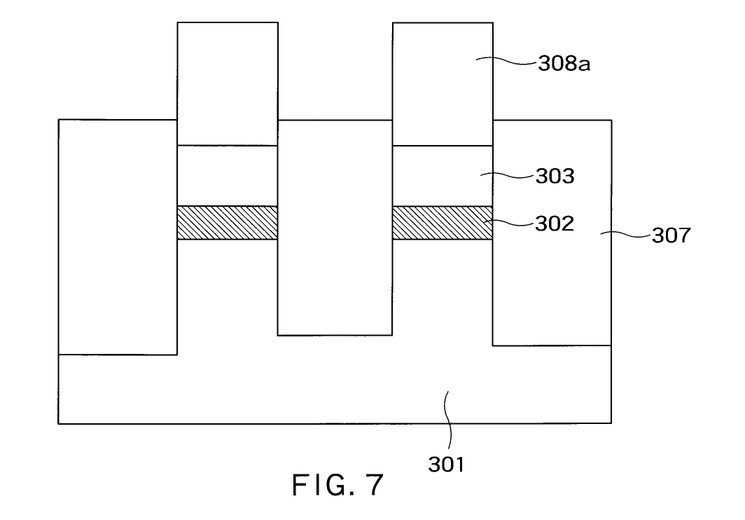

Next, as shown in FIG. 7, the conductive layer 308 is planarized by CMP using the insulation film 307 as a stopper. Then, the silicon oxide film 307 is selectively etched back using a method capable of performing etching with a selection ratio to the silicon nitride film to form a floating gate electrode 308a. After the above, the structure of FIG. 7 is obtained.

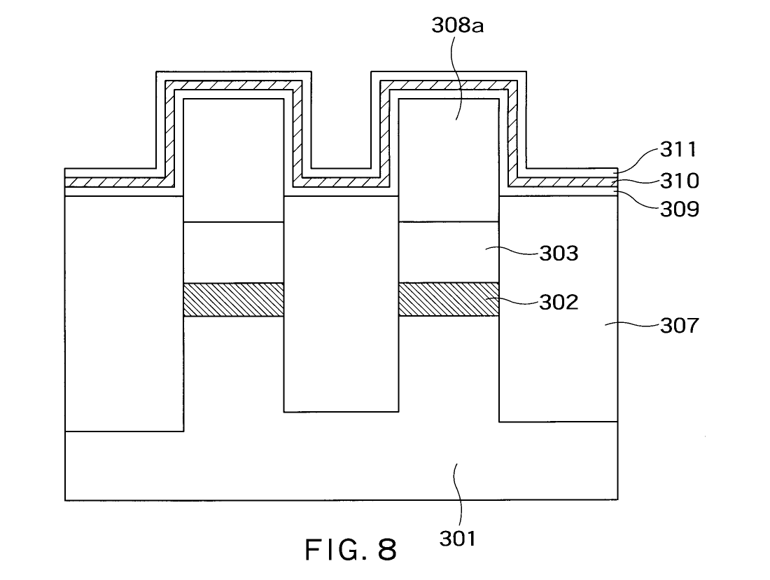

Next, as shown in FIG. 8, a silicon oxide film 309 is formed to 1 nm to 5 nm on the structure of FIG. 7. Then, a high-dielectric insulation film 310 is formed to a thickness in the range of one atomic layer to 5 nm on the upper portion of the silicon oxide film 309. At the time, a precursor containing carbon and nitrogen is used as a precursor of the high-dielectric insulation film 310. Then, a silicon oxide film 311 is formed to a thickness of 1 nm to 5 nm on the upper portion of the high-dielectric insulation film 310. After the above, the structure of FIG. 8 is obtained. The silicon oxide film 309, the high-dielectric insulation film 310, and the silicon oxide film 311 correspond to the second insulation film 105 of FIG. 1.

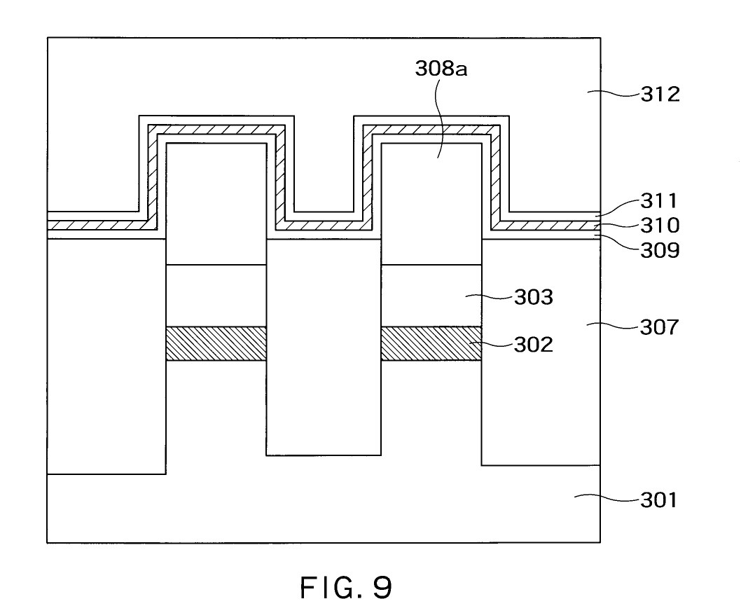

Next, as shown in FIG. 9, a second conductive layer 312 is formed on the silicon oxide film 311. The second conductive layer 312 acts as a control gate electrode. Then, an insulation film such as a silicon oxide film and the like which acts as a hard mask for a processing is formed. Then, a photoresist is coated. Then, the photoresist is patterned by exposure drawing. After the above, the structure of FIG. 9 is obtained.

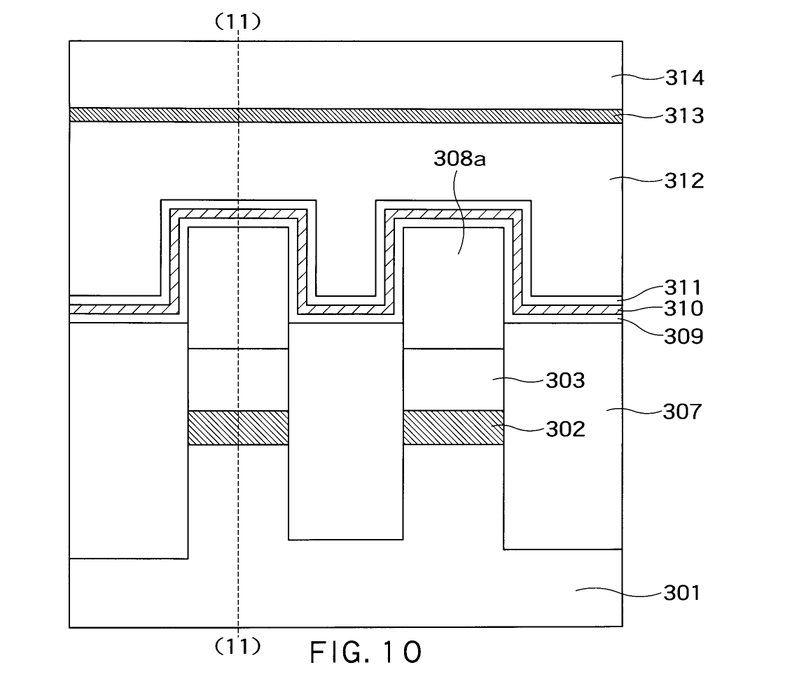

Next, as shown in FIG. 10, the silicon oxide film is processed using the photoresist as the mask. Then, the photoresist is removed. Then, the second conductive layer 312, the second insulation film 105 (309 to 311), the first conductive layer 303, and the first insulation layer 302 are processed using the silicon oxide film as the hard mask. Then, a side wall insulation film 313 is formed so that it comes into contact with the first insulation film 302, the first conductive layer 303 formed on the first insulation film 302, the second insulation film 105 having the high-dielectric insulation film 310 formed on the first conductive layer 303, and the second conductive layer 312 formed on the second insulation film 105. Then, an inter-layer insulation film 314 is formed. After the above, the structure of FIG. 10 is obtained.

The side wall insulation film 313 is formed at 400° C. to 600° C. using ALD using, for example, BTBAS and oxygen. Although the example, in which BTBAS and oxygen are used as the precursor when the side wall insulation film 313 is formed is shown, other material, for example, TrDMAS (3-Dimethyl Amino Silane) and TDMAS (4-Dimethyl Amino Silane) which contain nitrogen, carbon, and hydrogen and does not contain chlorine and a halogen element may be used as the precursor. Further, a side wall SiO₂ may be formed without using ALD in such a manner that after a Si thin film is formed using a silicon material such as SiH₄, Si₂H₆, and the like which does not contain chlorine, the Si thin film is exposed to an atmosphere containing oxidant, for example, O₃, H₂O, O₂, O*, and the like.

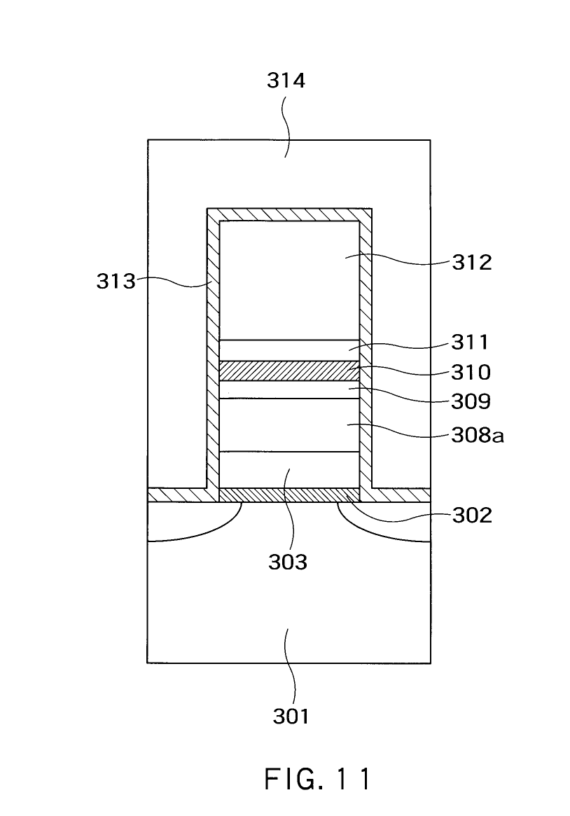

FIG. 11 is a sectional view of FIG. 10 in the sectional direction of a broken line (11). As shown in FIG. 11, the second insulation film 105 has a stacked structure containing the high-dielectric insulation film 310. After the side wall insulation film 313 is formed, an ordinary wiring process and the like is performed. After the above, the non-volatile semiconductor memory device of the first embodiment of the invention is obtained.

According to the manufacturing method of the first embodiment of the present invention, since the side wall insulation film 313 is formed at 400° C. to 600° C. using the precursor containing carbon and nitrogen as the precursor of the high-dielectric insulation film 310 and using ALD using BTBAS and oxygen, the chlorine concentration in the side wall insulation film 107 can be suppressed to a low level as well as the high-dielectric insulation film can be introduced to the second insulation film 105.

### SECOND EMBODIMENT

Next an second embodiment of the present invention will be explained. Although the side wall insulation film is formed using the precursor of the silicon oxide film which does not contain chlorine in the first embodiment of the present invention, a side wall insulation film is formed using a precursor containing chlorine in the second embodiment of the present invention. Note that same contents as those of the first embodiment of the present invention are not explained in the second embodiment of the present invention.

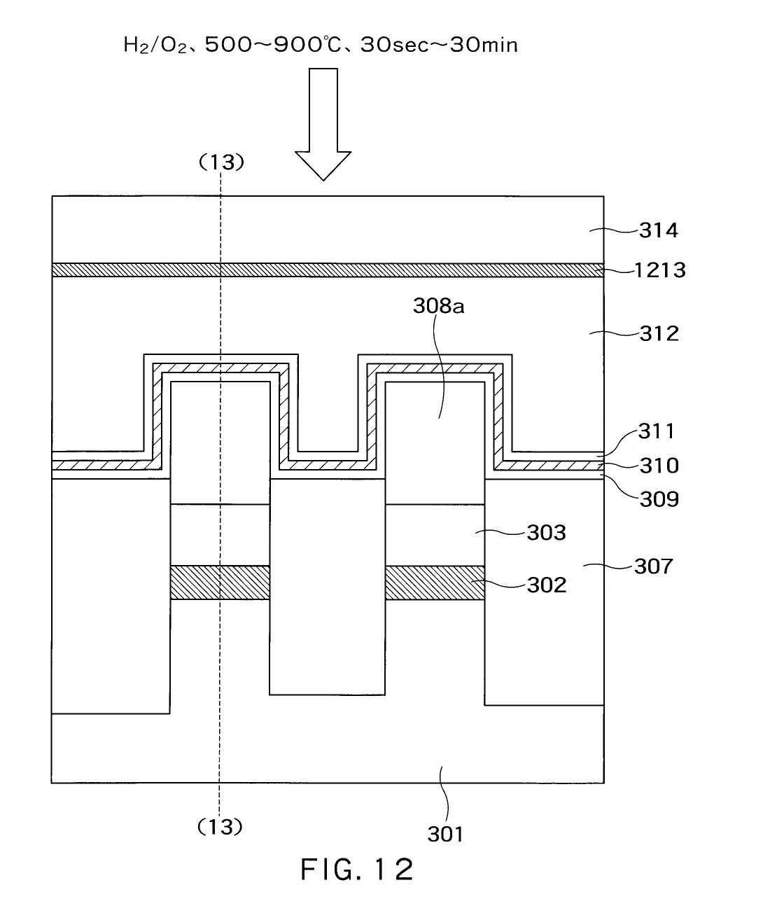

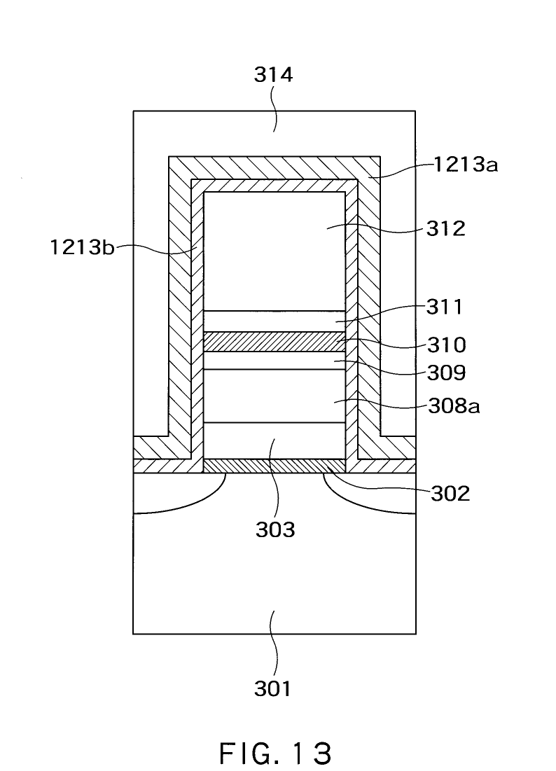

FIG. 12 is a sectional view of a structure of a cell transistor of the non-volatile semiconductor memory device of the second embodiment of the present invention. In the second embodiment of the present invention, a side wall insulation film 1213 contains a layer having a low chlorine concentration and a layer having a high chlorine concentration. FIG. 13 is a sectional view of FIG. 12 in the sectional direction of a broken line (13).

As shown in FIG. 13, the side wall insulation film 1213 contains a low concentration side wall insulation film 1213a and a high concentration side wall insulation film 1213b. An inter-layer insulation film 314 is formed on the low concentration side wall insulation film 1213a, and the high concentration side wall insulation film 1213b is in contact with a first insulation film 302, a first conductive layer 303, a floating gate electrode 308a, a second insulation film 105 (silicon oxide film 309, high-dielectric insulation film 310, and silicon oxide film 311), and a second conductive layer 312. The low concentration side wall insulation film 1213a has a chlorine concentration of 1×10¹⁹ atoms/cm⁻³ or less, and the high concentration side wall insulation film 1213b has a chlorine concentration of 1×10²⁰ atoms/cm⁻³.

According to the second embodiment of the present invention, since the absolute amount of chlorine in the side wall insulation film 1213 is smaller than that in the side wall insulation film 107 of the first embodiment of the present invention (refer to FIG. 1), and the chlorine which is liable to desorb is desorbed in heat treatment processing, only the chlorine which is unlike to diffuse in a assembly and testing process, remains. Accordingly, the reaction of chlorine with the first insulation film 302 and the second insulation film 105 is greatly suppressed in the assembly and testing process. As a result, since creation of oxygen deficiency is greatly suppressed in the high-dielectric insulation film 310, the charge holding characteristics of a cell transistor can be greatly improved in a cell size of 60 nm or less.

The side wall insulation film 1213 may be contain a single layer film of any one of, for example, aluminum oxide (Al₂O₃) film having a relative permittivity of about 8, a magnesium oxide (MgO) film having a relative permittivity of about 10, an yttrium oxide (Y₂O₃) film having a relative permittivity of about 16, a hafnium oxide (HfO₂) film having a relative permittivity of about 22, a zirconium oxide (ZrO₂) film, and lanthanum oxide (La₂O₃). Further, the side wall insulation film 1213 may be an insulation film containing a ternary compound such as a hafnium silicate (HfSiO) film and a hafnium-aluminate (HfAlO) film. That is, the side wall insulation film 1213 may contain oxide or nitride containing at least any one element of silicon (Si), aluminum (Al), magnesium (Mg), yttrium (Y), hafnium (Hf), zirconium (Zr), and lanthanum (La). Further, the high-dielectric insulation film 310 may be used as a part of the tunnel insulation film 302.

### <Method of Manufacturing Non-volatile Semiconductor Memory Device of the Second Embodiment of the Present Invention>

Next, a method of manufacturing the non-volatile semiconductor memory device of the second embodiment of the present invention will be explained referring to FIGS. 12 and 13. Note that explanation of the same contents as those of the manufacturing method of the first embodiment of the present invention is omitted.

As shown in FIG. 12, after the side wall insulation film 1213 is formed, the chlorine concentration of the side wall insulation film 1213 is reduced by subjecting it to a heat treatment at a temperature of 500° C. to 900° C. for 30 seconds to 30 minutes in an atmosphere containing hydrogen and oxygen. In this case, since chlorine located nearer to the surface of the side wall insulation film 1213 is liable to be desorbed, the chlorine concentration is higher in the inside of the insulation film 1213 and lower on the surface thereof in the chlorine profile in the side wall insulation film 1213. As a result, the low concentration side wall insulation film 1213a and the high concentration side wall insulation film 1213b are formed. The total amount of chlorine in the side wall insulation film 1213 is reduced by the amount of chlorine which is desorbed from surface side of the side wall insulation film 1213 (low concentration side wall insulation film 1213a) by the heat treatment. As a result, the chlorine concentration is about 1×10¹⁹ atoms/cm⁻³ in the low concentration side wall insulation film 1213a and about 1×10²⁰ atoms/cm⁻³ in the high concentration side wall insulation film 1213b.

According to the manufacturing of the second embodiment of the present invention, after the side wall insulation film 1213 is formed, since it is subjected to the heat treatment at 500° C. to 900° C. for 30 seconds to 30 minutes in the atmosphere containing hydrogen and oxygen, the low concentration side wall insulation film 1213a can be formed to the surface side of the side wall insulation film 1213.

### COMPARATIVE EXAMPLE

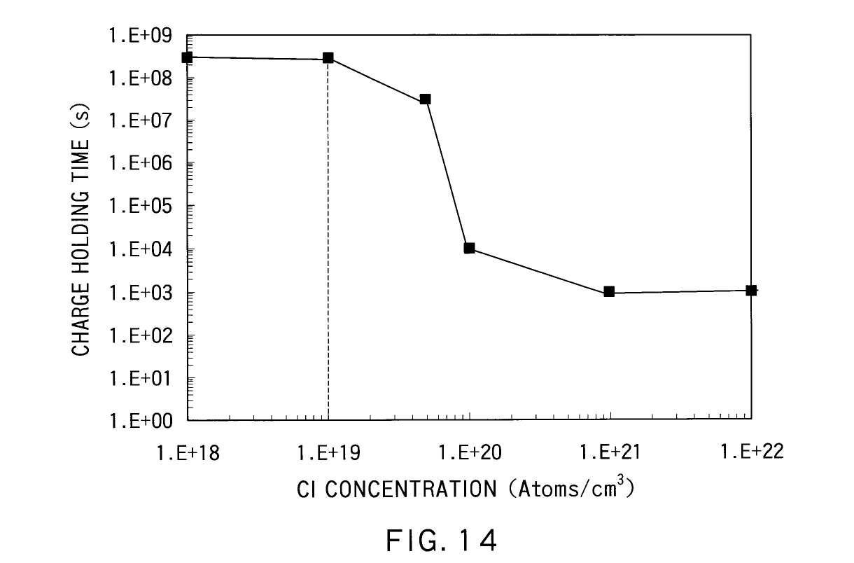

Next, a comparative example will be explained referring to FIG. 14. In the comparative example, chlorine is contained in a side wall insulation film in the amount at least 1×10¹⁹ atoms/cm³.

When the side wall insulation film contains chlorine in the amount at least 1×10¹⁹ atoms/cm³, since the chlorine disperses in a high-dielectric insulation film and reacts to it in a heat process after the side wall is formed, the coupling of metal with oxygen is cut off, oxygen deficiency is formed in the high-dielectric insulation film, a shallow trap level which acts as a low electric field leak current path is created in the high-dielectric insulation film as well as a charge is accumulated therein when data is written or deleted, and the shallow trap level is made to a deep trap level which discharges a charge captured while the high-dielectric insulation film is left as it is. As a result, in the comparative example, the charge holding characteristics of a cell transistor is greatly deteriorated.

Specifically, the side wall insulation film is formed at 600° C. to 800° C. by CVD using dichlorosilane and oxygen dinitride. In the method, the coupling of metal with oxygen in the high-dielectric insulation film is cut off by the chlorine which is generated as a reaction byproduct when the side wall insulation film is formed, or the chlorine which remains in the insulation film, oxygen deficiency is formed in the high-dielectric insulation film. After that, the shallow trap level which acts as the low electric field leak current path is created in the high-dielectric insulation film as well as the charge is accumulated therein when data is written or deleted, and the shallow trap level is made to a deep trap level which discharges a charge captured while the high-dielectric insulation film is left as it is. As a result, in prior art, the charge holding characteristics of the cell transistor is greatly deteriorated. Since the deterioration is mainly caused by a lateral chemical damage, the deterioration is unlike to occur when a cell size is large because the ratio of the high-dielectric insulation film affected from an edge is small. However, as the size of the cell transistor is reduced, the ratio of the high-dielectric insulation film affected by the edge increases, thereby cell characteristics are prominently deteriorated.

FIG. 14 is a graph showing the relation between Cl concentration and a charge holding time of the cell transistor of the comparative example. An increase of the chlorine concentration in the interface between the side wall insulation film and electrode insulation film decreases the charge holding time, and when the chlorine concentration exceeds 1×10¹⁹ atoms/cm³, the charge holding time is greatly decreased. As a result, it cannot be guaranteed to hold a charge for a long period (for example, 10 years). It is shown that the tendency is the same even if the cell size is 60 nm or less.

What is claimed is:

1. A semiconductor memory device having a cell size of 60 nm or less comprising:
a tunnel insulation film formed in a channel region of a silicon substrate containing a burying insulation film;
a first conductive layer formed on the tunnel insulation film;
an inter-electrode insulation film formed on the burying insulation film and the first conductive layer;
a second conductive layer formed on the inter-electrode insulation film;
a side wall insulation film formed on the side walls of the first conductive layer, the second conductive layer, and the inter-electrode insulation film; and
an inter-layer insulation film formed on the side wall insulation film,
wherein the tunnel insulation film or the inter-electrode insulation film contains a high-dielectric insulation film; and
the side wall insulation film contains a predetermined concentration of carbon and nitrogen as well as chlorine having a concentration of 1×10¹⁹ atoms/cm³ or less.

2. The semiconductor memory device according to claim 1, wherein the side wall insulation film contains chlorine having a concentration of 1×10¹⁹ atoms/cm³ or less in a region in contact with the inter-layer insulation film.

3. The semiconductor memory device according to claim 2, wherein the side wall insulation film has a stacked structure formed of a low concentration side wall insulation film which is in contact with the inter-layer insulation film and contains chlorine having a concentration of 1×10¹⁹ atoms/cm³ or less, and a high concentration side wall insulation film which is in contact with the low concentration side wall insulation film and contains chlorine having a concentration of 1×10²⁰ atoms/cm³ or more.

4. A method of manufacturing a semiconductor memory device having a cell size of 60 nm or less comprising:
forming a tunnel insulation film to a channel region of a silicon substrate;
forming a first conductive layer on the tunnel insulation film;
forming an inter-electrode insulation film on the first conductive layer;
forming a second conductive layer on the inter-electrode insulation film;
processing the second conductive layer, the inter-electrode insulation film, and the first conductive layer;
forming a side wall insulation film which contains a predetermined concentration of carbon and nitrogen as well as chlorine having a concentration of 1×10¹⁹ atoms/cm³ or less to the side walls of the first conductive layer, the second conductive layer, and the inter-electrode insulation film;
forming an inter-layer insulation film on the side wall insulation film; and
forming a high-dielectric insulation film in the process for forming the tunnel insulation film or the inter-electrode insulation film.

5. The method of manufacturing the semiconductor memory device according to claim 4, wherein the side wall insulation film is formed at 400° C. to 600° C. by an atomic layer deposition method using a precursor containing silicon and carbon in the process for forming the side wall insulation film.

6. A method of manufacturing a semiconductor memory device having a cell size of 60 nm or less comprising:
forming a tunnel insulation film to a channel region of a silicon substrate;
forming a first conductive layer on the tunnel insulation film;
forming an inter-electrode insulation film on the first conductive layer;
forming a second conductive layer on the inter-electrode insulation film,
processing the second conductive layer, the inter-electrode insulation film, and the first conductive layer;
forming a side wall insulation film which contains carbon, nitrogen, and chlorine, to the side walls of the first conductive layer, the second conductive layer, and the inter-electrode insulation film;
forming an inter-layer insulation film on the side wall insulation film;
reducing the concentration of the chlorine contained in the side wall insulation film to 1×10¹⁹ atoms/cm³ or less by subjecting the entire surface of the side wall insulation film to a heat treatment in an atmosphere containing hydrogen and oxygen; and
forming a high-dielectric insulation film in the process for forming the tunnel insulation film or the inter-electrode insulation film.

7. The method of manufacturing the semiconductor memory device according to claim 6, wherein the side wall insulation film is formed at 400° C. to 600° C. by an atomic layer deposition method using a precursor containing silicon and carbon in the process for forming the side wall insulation film.

8. The method of manufacturing the semiconductor memory device according to claim 6, wherein a stacked structure which is formed of a low concentration side wall insulation film which is in contact with the inter-layer insulation film and contains chlorine having a concentration of 1×10¹⁹ atoms/cm³ or less and a high concentration side wall insulation film which is in contact with the low concentration side wall insulation film and contains chlorine having a concentration of 1×10²⁰ atoms/cm³ or more is formed in the process for forming the side wall insulation film.

9. The method of manufacturing the semiconductor memory device according to claim 8, wherein the side wall insulation film is formed at 400° C. to 600° C. by an atomic layer deposition method using a precursor containing silicon and carbon in the process for forming the side wall insulation film.
